(19) United States
(12) Patent Application Publication
(10) Pub. No.: US 2011/0151599 A1
(43) Pub. Date: Jun. 23, 2011

(54) Vapor deposition apparatus having improved carrier gas supplying structure and method of manufacturing an organic light emitting display apparatus by using the vapor deposition apparatus

(76) Inventors: Heung-Yeol Na, Yongin-City (KR); Min-Jae Jeong, Yongin-city (KR); Kil-Won Lee, Yongin-city (KR)

(21) Appl. No.: 12/805,667

(22) Filed: Aug. 12, 2010

(30) Foreign Application Priority Data
Dec. 23, 2009 (KR) 10-2009-0130025

(51) Int. Cl. H01L 51/56

(52) U.S. Cl. 438/22; 118/715; 257/E51.018

(57) ABSTRACT

A vapor deposition apparatus includes a canister configured to contain a vapor deposition source, the canister including a gas inlet and a gas outlet opposite to each other, a heater configured to heat the canister, a chamber in fluid communication with the canister, the chamber being configured to contain a vapor deposition target, and a carrier gas supplying unit configured to supply a carrier gas into the canister.

### BACKGROUND

1. Field of the Invention

Example embodiments relate to a vapor deposition apparatus. More particularly, example embodiments relate to a vapor deposition apparatus having an improved carrier gas supplying structure for moving sublimated vapor deposition source to a target, and a method of manufacturing an organic light emitting display apparatus by using the vapor deposition apparatus.

2. Description of the Related Art

In a method of manufacturing a thin film, e.g., a thin film transistor (TFT) of an organic light-emitting display apparatus, a vapor deposition device may be used to sublimate a vapor deposition source and to attach the sublimated vapor deposition source onto a vapor deposition target, e.g., a substrate. The vapor deposition device may include a canister charged with the vapor deposition source, a heater for heating the canister, and a support, e.g., in a chamber, for the vapor deposition target.

### SUMMARY

Embodiments are directed to a vapor deposition apparatus and a method of manufacturing an organic light emitting display apparatus by using the vapor deposition apparatus, which substantially overcome one or more of the problems due to the limitations and disadvantages of the related art.

It is therefore a feature of an embodiment to provide a vapor deposition apparatus having a structure capable of preventing fluid turbulence in a canister.

It is therefore another feature of an embodiment to provide a vapor deposition apparatus having a structure capable of reducing a temperature difference between portions inside the canister.

It is still another feature of an embodiment to provide a method of manufacturing an organic light emitting display apparatus by using a vapor deposition apparatus having one or more of the above features.

At least one of the above and other features and advantages may be realized by providing a vapor deposition apparatus, including a canister configured to contain a vapor deposition source, the canister including a gas inlet and a gas outlet opposite to each other, a heater configured to heat the canister, a chamber in fluid communication with the canister, the chamber being configured to contain a vapor deposition target, and a carrier gas supplying unit configured to supply a carrier gas into the canister.

The carrier gas supplying unit may include a coil inside the canister for guiding the carrier gas so as to circulate in the canister before the carrier gas is injected into the canister through the gas inlet. The coil may have a helical shape. The coil may have a gradually decreasing diameter toward the gas inlet. The coil may be a heat exchanger. The entire coil may be inside the canister. The coil may be connected between the gas inlet and a gas carrier storage unit. The carrier gas may include an argon (Ar) gas. The vapor deposition source may be in a powder state. The gas inlet and the gas outlet may be aligned along a same axis traversing the canister. The gas inlet and the gas outlet may be on opposite sides of the canister.

At least one of the above and other features and advantages may also be realized by providing a method of manufacturing an organic light emitting display apparatus, including preparing a canister including gas inlet and outlets of a carrier gas which are disposed opposite to each other, preparing a chamber connected to the canister through the gas outlet, disposing an amorphous silicon to be used as a semiconductor layer of a TFT in the chamber, charging metal catalyst powders to be deposited on the amorphous silicon in the canister, sublimating the metal catalyst powders by heating the canister, depositing the sublimated metal catalyst on a surface of the amorphous silicon by injecting a carrier gas through the gas inlet of the carrier gas and moving the sublimated metal catalyst carried on the carrier gas to the chamber through the gas outlet, and performing thermal annealing in such a way that the deposited metal catalyst is diffused and crystallized in the amorphous silicon. The method may further include guiding the carrier gas through a coil so as to circulate in the canister before the carrier gas is injected into the canister through the gas inlet.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic diagram of a vapor deposition apparatus according to an embodiment;

FIG. 2 illustrates an enlarged perspective view of a coil in a vapor deposition apparatus according to an embodiment; and

FIG. 3 illustrates a cross-sectional view of an organic light emitting display apparatus manufactured using a vapor deposition apparatus according to an embodiment.

### DETAILED DESCRIPTION

Korean Patent Application No. 10-2009-0130025, filed on Dec. 23, 2009, in the Korean Intellectual Property Office, and entitled: “Vapor Deposition Apparatus Having Improved Carrier Gas Supplying Structure and Method of Manufacturing Organic Light Emitting Display Apparatus by Using Vapor Deposition Apparatus,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of elements and regions may be exaggerated for clarity of illustration. It will also be understood that when a layer or element is referred to as being “on” another element or substrate, it can be directly on the other element or substrate, or intervening elements may also be present. In addition, it will also be understood that when an element is referred to as being “between” two elements, it can be the only element between the two elements, or one or more intervening elements may also be present. Like reference numerals refer to like elements throughout.

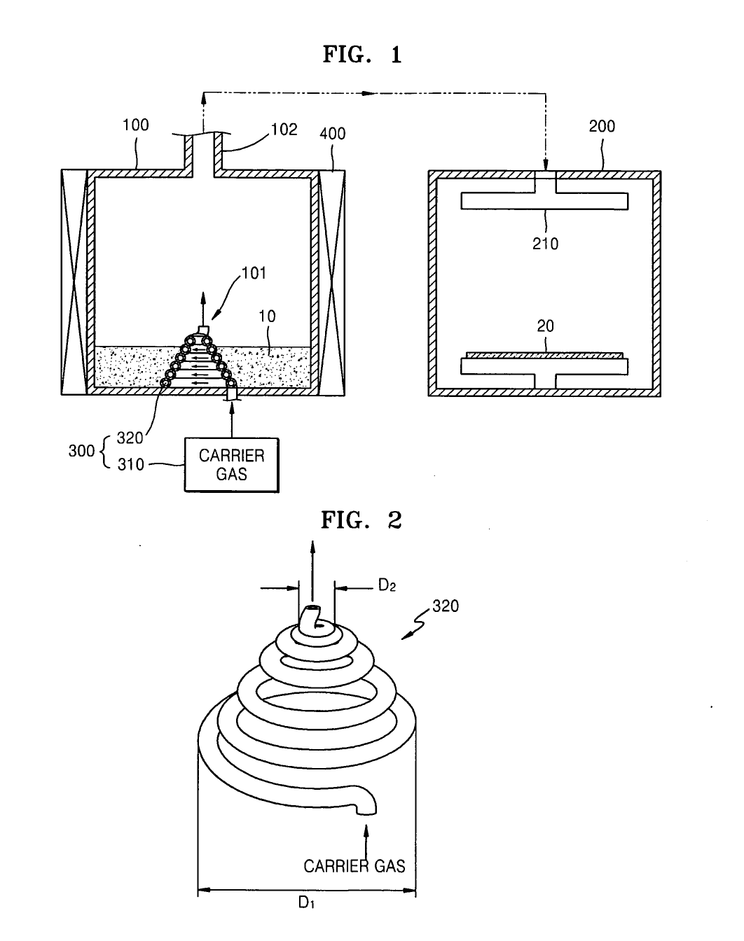

Hereinafter, example embodiments of a vapor deposition apparatus will be described in detail with reference to FIG. 1. FIG. 1 illustrates a schematic diagram of a vapor deposition apparatus according to an embodiment.

Referring to FIG. 1, the vapor deposition apparatus may include a canister 100 charged with a vapor deposition source 10, a heater 400 for heating the canister 100 in order to sublimate the vapor deposition source 10, a chamber 200 connected to the canister 100 and in which a vapor deposition target 20 is installed, and a carrier gas supplying unit 300 for injecting an inactive carrier gas, e.g., argon (Ar) gas, into the canister 100 through a gas inlet 101. The carrier gas transfers the sublimated vapor deposition source 10 to the chamber 200 via the gas outlet 102.

Thus, the vapor deposition source 10, e.g., in a form of powder, may be placed in the canister 100, and the heater 400 may heat the canister 100 in order to sublimate the vapor deposition source 10 therein. Then, the vapor deposition source 10 may be carried with the carrier gas through the gas outlet 102 into the chamber 200. The vapor deposition source 10 moved to the chamber 200 may be sprayed onto the vapor deposition target 20 through a sprayer 210 to be attached to a surface of the vapor deposition target 20.

The canister 100 may be configured to have the gas inlet and outlet 101 and 102 opposite each other. That is, as illustrated in FIG. 1, the gas inlet 101 and the gas outlet 102 may be arranged to be on opposite sides of the canister 100. For example, the gas inlet 101 may be arranged on a bottom side of the canister 100, i.e., a side supporting the canister 100, and the gas outlet may be arranged on a top side of the canister 100, i.e., a side opposite and above the bottom side of the canister 100. For example, the gas inlet and outlet 101 and 102 may overlap each other, e.g., the gas inlet and outlet 101 and 102 may be aligned to be on a same vertical axis with respect to the bottom side of the canister 100. The positional relationship of the gas inlet and outlet 101 and 102 on opposing sides of the canister 100 may be effectively used to remove fluid turbulence inside the canister 100.

That is, when a gas inlet is disposed on a same side as the gas outlet, e.g., when both gas inlet and outlet are on a top side of a canister, the carrier gas injected through the gas inlet collides with the vapor deposition source and returns into the gas outlet. Since the carrier gas is directed in two directions, e.g., in a downward direction when injected into the canister and in an upward direction when ejected out of the canister, fluid turbulence may occur inside the canister. In this case, fluid may not flow smoothly. Further, the vapor deposition source, i.e., in the form of powder, may disperse due to the fluid turbulence, and a portion of the vapor deposition source in a solid form, i.e., not sublimated, may be carried with the carrier gas into the chamber, thereby causing non-uniform deposition on the vapor deposition target.

According to embodiments, however, when the gas inlet 101 and the gas outlet 102 are on opposite sides of the canister 100, e.g., respective lower and upper portions of the canister 100, the carrier gas is directed in a single direction, e.g., only in an upward direction. Therefore, fluid turbulence in the canister 100 may be prevented or substantially minimized. For example, the carrier gas is injected through the gas inlet 101 in an upward direction, absorbs the sublimated vapor deposition source 10, and continues in the upward direction to be ejected through the gas outlet 102 disposed opposite to the gas inlet 101 without turbulence. Accordingly, the sublimated vapor deposition source 10 may be smoothly moved to the chamber 200, e.g., with substantially reduced dispersion or disturbance.

The carrier gas supplying unit 300 may include a carrier gas storage unit 310 and a coil 320. The coil 320 may function as a helically wound tube for preheating the carrier gas supplied from the carrier gas storage unit 310 by heat of the canister 100 before the carrier gas is injected into the canister 100 through the gas inlet 101. If the carrier gas is not preheated, e.g., is at room temperature of about 25° C., before injection into the canister 100, e.g., maintaining an inner temperature at about 80° C., a temperature difference between the newly injected carrier gas, e.g., a portion of the carrier gas in close proximity to the gas inlet 101, and the contents of the canister 100, e.g., a portion of the carrier gas in close proximity to the gas outlet 102, may be large.

The coil 320 may have a helical shape with a plurality of connected rings for ensuring a long path even in a narrow space, as shown in FIGS. 1 and 2. While the carrier gas is moving through the helical coil 320, heat exchange occurs between the carrier gas in the coil 320 and the inside of the canister 100. The carrier gas that is preheated by the heat exchange in the coil 320 is injected into the canister 100 through the gas inlet 101. Thus, a temperature difference between portions inside the canister 100 may be substantially reduced, as compared to a conventional vapor deposition apparatus, i.e., where a carrier gas at room temperature is directly injected into a canister without being preheated. Since the temperature difference between portions inside the canister 100 is substantially reduced, the vapor deposition source 10 in the canister 100 may be uniformly sublimated, and a uniform amount of the vapor deposition source 10 may be supplied to the chamber 200 during vapor deposition.

In detail, as illustrated in FIG. 2, a helical path of the coil 320 may be configured as a circular cone with a decreasing diameter, i.e., the plurality of connected rings may have decreasing diameters. For example, a bottom of the coil 320, i.e., a bottom-most ring, may have a first diameter D₁ that decreases gradually, so a top of the coil 320, i.e., a top-most ring, contacting the gas inlet 101 may have a second diameter D₂ that is smaller than the first diameter D₁, i.e., D₁>D₂. It is noted that the bottom of the coil 320 may be connected to the carrier gas storage unit 310, so the carrier gas may be injected from the carrier gas storage unit 310 to the bottom of the coil 320. Then, the carrier gas may move within the coil 320 from the bottom to the top in order to be transferred from the top of the coil 320 to the gas inlet 101. For example, the bottom of the coil 320 may be positioned on the bottom side of the canister 100, e.g., the entire coil 320 may be inside the canister 100. A length of the coil 320, e.g., size and number of rings, may be adjusted to provide sufficient time for heat-exchange.

It is noted that if a coil is configured as a circular cylinder with a constant diameter, i.e., D₁=D₂, a length of a helical path required to achieve sufficient heat exchange, i.e., to sufficiently heat the carrier gas, may be too long, thereby occupying a large space within the canister 100, and reducing an available space for the vapor deposition source 10 within the canister 100. According to the present embodiment, however, the coil 320 may be configured as a circular cone with a non-constant diameter, thereby occupying a reduced space within the canister 100 while ensuring sufficient time for preheating the carrier gas. Therefore, a uniform sublimation of the vapor deposition source 10 may occur.

The above-described vapor deposition apparatus may be effectively used in, e.g., a method of manufacturing a TFT of an organic light emitting display apparatus. That is, when a metal catalyst is deposited in order to crystallize an amorphous semiconductor layer of the TFT, the vapor deposition apparatus may be used. In this case, the vapor deposition source 10 may include nickel (Ni) powders, and the carrier gas may include argon (Ar) gases.

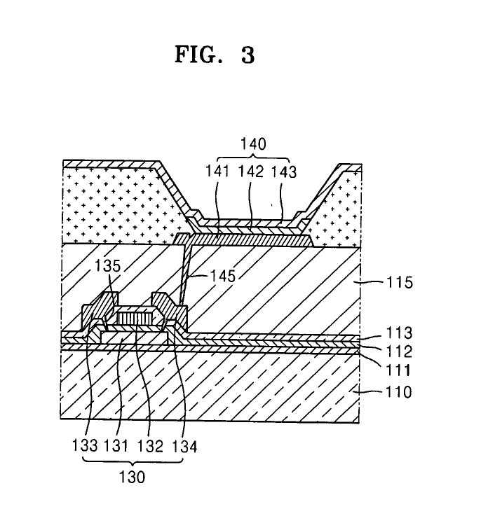

In order to explain use of the vapor deposition apparatus in the method of manufacturing a TFT of an organic light emitting display apparatus, a structure of the organic light emitting display apparatus will now be described with reference to FIG. 3. Referring to FIG. 3, an organic light emitting display apparatus may include a TFT 130 and an organic light emitting device 140 electrically connected to the TFT 130.

The TFT 130 may include a polycrystalline silicon layer 131, a first insulating layer 112, and a gate electrode 132. A second insulating layer 113 may be disposed on the gate electrode 132, and source and drain electrodes 133 and 134 may be electrically connected to the polycrystalline silicon layer 131 through a contact hole 135. One of the source and drain electrodes 133 and 134 may be electrically connected to a first electrode 141 of the organic light emitting device 140.

A passivation layer 115 may be formed between the source and drain electrodes 133 and 134, and the first electrode 141 so as to protect the TFT 130. The passivation layer 115 may include an inorganic insulating layer and/or an organic insulating layer. The inorganic insulating layer may include, e.g., one or more of SiO₂, SiNₓ, SiON, Al₂O₃, TiO₂, Ta₂O₅, HfO₂, ZrO₂, BST, PZT, or the like. The organic insulating layer may include a polymer, e.g., PMMA or PS, a phenol group-containing polymer derivative, an acrylic polymer, an imide-based polymer, an arylether-based polymer, an amide-based polymer, a fluorinated polymer, a p-xylene-based polymer, a vinylalcohol-based polymer, or a blend thereof. The passivation layer 115 may be formed as a composite stack structure including an inorganic insulating layer and an organic insulating layer.

In a bottom-emission type organic light-emitting display apparatus in which images are realized toward a substrate 110, the first electrode 141 of the organic light emitting device 140 may be formed as a transparent electrode, and a second electrode 143 may be formed as a reflective electrode. In this case, the first electrode 141 may be formed of a material with a high work function, e.g., indium tin oxide (ITO), indium zinc oxide (IZO), zinc oxide (ZnO) or indium(III) oxide (In₂O₃), and the second electrode 143 may be formed of a material with a low work function, e.g., silver (Ag), magnesium (Mg), aluminum (Al), platinum (Pt), lead (Pb), gold (Au), nickel (Ni), neodymium (Nd), iridium (Ir), chromium (Cr), lithium (Li), or calcium (Ca).

In a top emission type organic light-emitting display apparatus in which images are realized toward an opposite direction to the substrate 110 in order to ensure an aperture ratio, the first electrode 141 may be formed as a reflective electrode, and the second electrode 143 may be formed as a transparent electrode. In this case, the reflective electrode as the first electrode 141 may be formed by forming Ag, Mg, Al, Pt, Pd, Au, Ni, Nd, Ir, Cr, Li, Ca or compounds thereof into a reflective layer, and then forming a material with a high work function, e.g., ITO, IZO, ZnO, or In₂O₃, into a layer on the reflective layer. In addition, the transparent electrode as the second electrode 143 may be formed by depositing a material with a low work function, e.g., Ag, Mg, Al, Pt, Pd, Au, Ni, Nd, Ir, Cr, Li, Ca or compounds thereof, and then forming a transparent conductive material such as ITO, IZO, ZnO, or In₂O₃ into a auxiliary electrode layer or a bus electrode line on the deposited material.

An organic light emitting layer 142 interposed between the first electrode 141 and the second electrode 143 emits light by electrically driving the first electrode 141 and the second electrode 143. The organic light emitting layer 142 may be a small molecular weight organic material or a polymer organic material.

When the organic light emitting layer 142 is formed of a small molecular weight organic material, a hole transport layer (HTL) and a hole injection layer (HIL) may be sequentially stacked in a direction towards the first electrode 141 with respect to the organic light emitting layer 142, and an electron transport layer (ETL) and an electron injection layer (EIL) may be sequentially stacked in a direction toward the second electrode 143 with respect to the organic light emitting layer 142. In addition, various additional layers may be formed if necessary. An organic material used for forming the organic light emitting layer 142 may be copper phthalocyanine (CuPc), N,N′-Di(naphthalene-1-yl)-N,N′-diphenyl-benzidine (NPB), tris-8-hydroxyquinoline aluminum (Alq3) or the like.

When the organic light emitting layer 142 is formed of a polymer organic material, only an HTL may be staked in a direction towards the first electrode 141 with respect to the organic light emitting layer 142. The polymer HTL may be formed of poly-(2,4)-ethylene-dihydroxy thiophene (PEDOT), polyaniline (PANI), or the like, and may be formed on the first electrode 141 by using ink jet printing or spin coating. The organic light emitting layer 142 formed of a polymer may be formed of PPV, soluble PPVs, cyano-PPV, polyfluorene, or the like. A color pattern may be formed using a general method, e.g., ink jet printing, spin coating, or heat transfer with a laser, in the organic light emitting layer 142.

Although not illustrated, a sealing member (not shown) for sealing the organic light emitting device 140, e.g., glass, may be formed on the organic light emitting device 140. Further, an absorbent (not shown) may be provided in order to absorb external moisture or oxygen.

A method of forming the organic light emitting display apparatus will now be described. First, a buffer layer 111 may be formed on the substrate 110. Next, amorphous silicon may be deposited on the buffer layer 111, and then may be crystallized into polycrystalline silicon. Amorphous silicon may be crystallized into polycrystalline silicon by using, e.g., a solid phase crystallization (SPC) method, a field enhanced rapid thermal annealing (FERTA) method, an excimer laser annealing (ELA) method, a sequential lateral solidification (SLS) method, a metal induced crystallization (MIC) method, a metal induced lateral crystallization (MILC) method, or a super grain silicon (SGS) method. Among them, when the SGS method is used, the vapor deposition apparatus according to example embodiments, i.e., as described previously with reference to FIGS. 1-2, may be effectively used.

The SGS method will now be described in detail. A capping layer (not shown), e.g., a silicon nitride layer or a silicon oxide layer, may be formed on an amorphous silicon layer by using a chemical vapor deposition (CVD) method, a plasma enhanced chemical vapor deposition (PECVD), or the like.

Next, metal catalyst powder, e.g., nickel (Ni), may be deposited on the capping layer via the vapor deposition apparatus. That is, the vapor deposition source 10 in the canister 100 may include Ni powder, and the substrate 110 with the amorphous silicon layer and the capping layer thereon, i.e., the vapor deposition target 20, may be installed in the chamber 200. Argon (Ar) gas may be supplied to the canister 100 from the carrier gas supplying unit 300 through the coil 320 and the gas inlet 101. The heater 400 may heat the canister 100, so the Ni powder within the canister 100 may be sublimated and carried with the Ar gas into the chamber 200 to be deposited onto the capping layer. Since the Ni is deposited via a vapor deposition apparatus according to example embodiments, the Ni may be uniformly supplied onto the capping layer and the vapor deposition process is stabilized.

Then, the amorphous silicon may be crystallized, e.g., using a thermal annealing method. The thermal annealing method may be performed by heating the amorphous silicon in a furnace for a long time, or by performing a rapid thermal annealing (RTA). The metal catalyst, i.e., the sublimated Ni on the capping layer, may diffuse into the amorphous silicon by the thermal annealing, and may form a seed layer on the amorphous silicon layer. The amorphous silicon may grow from the seed layer, and may reach neighboring grains. Then, a grain boundary may be formed, and the amorphous silicon may be completely crystallized.

After the amorphous silicon is crystallized, the capping layer may be removed. Then, the first insulating layer 112 and the second insulating layer 113 may be sequentially formed, e.g., of SiO₂, SiNₓ, etc.

The source and drain electrodes 133 and 134 may be formed on the second insulating layer 113, and may be connected to the polycrystalline silicon layer 131 that is a semiconductor layer through the contact hole 135. Then, the passivation layer 115 may be formed, and then the organic light emitting device 140 may be formed on the passivation layer 115.

Thus, a metal catalyst may be uniformly supplied by using the vapor deposition apparatus according to example embodiments. Therefore, an amorphous silicon layer, i.e., a semiconductor layer of a TFT, may be crystallized into a polycrystalline silicon layer when an organic light emitting display apparatus is manufactured. Since the metal catalyst is uniformly supplied during crystallization of the amorphous silicon, sizes of grains of the polycrystalline silicon layer 131 may be uniform.

In the vapor deposition apparatus according to example embodiments, since the gas inlet and the gas outlet are disposed opposite to each other, fluid turbulence may be prevented in the canister. In addition, since a carrier gas is appropriately preheated and is supplied, a temperature difference between portions inside the canister may be substantially reduced. Thus, when the vapor deposition apparatus is used in a method of manufacturing an organic light emitting display apparatus, a metal catalyst as a vapor deposition source may be uniformly and stably supplied to an amorphous semiconductor layer as a vapor deposition target, and thus the semiconductor layer may be uniformly crystallized.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A vapor deposition apparatus, comprising:
a canister configured to contain a vapor deposition source, the canister including a gas inlet and a gas outlet opposite to each other;
a heater configured to heat the canister;
a chamber in fluid communication with the canister, the chamber being configured to contain a vapor deposition target; and
a carrier gas supplying unit configured to supply a carrier gas into the canister.

2. The vapor deposition apparatus as claimed in claim 1, wherein the carrier gas supplying unit includes a coil inside the canister, the carrier'gas being configured to pass through the coil before being injected into the canister through the gas inlet.

3. The vapor deposition apparatus as claimed in claim 2, wherein the coil has a helical shape.

4. The vapor deposition apparatus as claimed in claim 3, wherein the coil has a gradually decreasing diameter toward the gas inlet.

5. The vapor deposition apparatus as claimed in claim 2, wherein the coil is a heat exchanger.

6. The vapor deposition apparatus as claimed in claim 2, wherein the entire coil is inside the canister.

7. The vapor deposition apparatus as claimed in claim 6, wherein the coil is connected between the gas inlet and a gas carrier storage unit.

8. The vapor deposition apparatus as claimed in claim 1, wherein the carrier gas includes an argon (Ar) gas.

9. The vapor deposition apparatus as claimed in claim 1, wherein the vapor deposition source is in a powder state.

10. The vapor deposition apparatus as claimed in claim 1, wherein the gas inlet and the gas outlet are aligned along a same axis traversing the canister.

11. The vapor deposition apparatus as claimed in claim 1, wherein the gas inlet and the gas outlet are on opposite sides of the canister.

12. A method of manufacturing an organic light emitting display apparatus, the method comprising:
placing a vapor deposition source in a canister, the canister including a gas inlet and a gas outlet opposite to each other;
placing a vapor deposition target in a chamber, the chamber being in fluid communication with the canister;
heating the canister with a heater, such that the vapor deposition source is sublimated;
injecting a carrier gas into the canister by a carrier gas supplying unit through the gas inlet, such that the carrier gas carries the sublimated vapor deposition source through the gas outlet into the chamber to be deposited onto the vapor deposition target; and
using the vapor deposition target, after deposition of the vapor deposition source thereon, as a semiconductor layer of a thin film transistor (TFT) in the organic light emitting display apparatus.

13. The method as claimed in claim 12, wherein the vapor deposition target is amorphous silicon, and the vapor deposition source is metal catalyst powder.

14. The method as claimed in claim 13, further comprising performing thermal annealing, such that the deposited metal catalyst is diffused and crystallized in the amorphous silicon.

15. The method as claimed in claim 13, wherein the metal catalyst includes nickel (Ni) powder.

16. The method as claimed in claim 12, wherein injecting the carrier gas into the canister includes guiding the carrier gas through a coil, such that the carrier gas circulates through the coil inside the canister before being injected into the canister through the gas inlet.

17. The method as claimed in claim 16, wherein the coil is formed to have a helical shape.

18. The method as claimed in claim 17, wherein the coil is formed as a circular cone with a decreasing diameter toward the gas inlet.

19. The method as claimed in claim 16, wherein guiding the carrier gas through the coil includes preheating the carrier gas by heat generated by the heater while the carrier gas is passing through the coil.

20. The method as claimed in claim 12, wherein the carrier gas includes an argon (Ar) gas.
